(19) United States
(12) Patent Application Publication
(10) Pub. No.: US 2012/0236507 A1
(43) Pub. Date: Sep. 20, 2012

(54) SENSOR MODULE, SENSOR DEVICE, METHOD FOR PRODUCING SENSOR DEVICE, AND ELECTRONIC APPARATUS

(75) Inventor: Yugo KOYAMA, Ina (JP)

(73) Assignee: SEIKO EPSON CORPORATION, Tokyo (JP)

(21) Appl. No.: 13/413,908

(22) Filed: Mar. 7, 2012

(30) Foreign Application Priority Data
Mar. 15, 2011 (JP) 2011-056253

(51) Int. Cl. H05K 7/06; H05K 3/30

(52) U.S. Cl. 361/728; 29/832

(57) ABSTRACT

A sensor module includes a supporting member having three support faces orthogonal to one another, three IC chips each having connection terminals and external connection terminals on the side thereof where an active face is located, the three IC chips attached to the support faces of the supporting member on the sides thereof where passive faces lying along the active faces are located, three vibrating gyro elements each having a base, vibrating arms extending from the base, and connection electrodes, and flexible wiring substrates connected to the external connection terminals of the IC chips, each vibrating gyro element is disposed on the side of the IC chip where the active face is located, the connection electrodes are attached to the connection terminals of each IC chip such that one principal surface lies along the support face, and the flexible wiring substrate has a reinforcing layer.

### BACKGROUND

1. Technical Field

The present invention relates to a sensor module, a sensor device provided with a sensor module, a method for producing a sensor device, and an electronic apparatus provided with a sensor module.

2. Related Art

In the past, in a sensor device that senses an acceleration or an angular velocity, a configuration using a sensor module provided with a sensor element and a circuit element having the function of driving the sensor element has been known.

For example, in JP-A-2005-292079 (FIG. 12) (hereinafter Patent Document 1), a gyro sensor (a piezoelectric oscillator) in which a sensor module provided with a gyro vibrating reed as a sensor element and a semiconductor device (hereinafter referred to as an IC chip) as a circuit element is housed in a package is disclosed.

In this configuration, the IC chip is firmly fixed to a supporting substrate and is electrically connected to a lead wiring section formed in the supporting substrate. Moreover, the sensor element (the gyro vibrating reed) is connected to a lead wire firmly fixed to the supporting substrate, whereby the sensor element (the gyro vibrating reed) is disposed in such a way that a space is left between the sensor element (the gyro vibrating reed) and the IC chip and the sensor element (the gyro vibrating reed) overlaps the IC chip in a plan view.

Incidentally, the gyro sensor (hereinafter referred to as the sensor device) of Patent Document 1 is disposed in such a way that, as the sensor device that responds to one detection axis (a sensing axis: for example, an axis orthogonal to a principal surface of the sensor element), a principal surface of the sensor element of the sensor module is nearly parallel to the bottom face of the package.

In recent years, there has been a demand for not only such a sensor device that responds to one axis, but also a sensor device that responds to two or three detection axes which cross one another.

To respond to two or three detection axes which cross one another, two or three sensor devices, each responding to one detection axis as in Patent Document 1, for example, may be prepared and installed in a target apparatus in their respective positions corresponding to the axes.

As a result, a considerable sensor device mounting space is required in the target apparatus, which may hamper miniaturization of the target apparatus.

Moreover, in the configuration described above, since two or three packages are required, the target device is relatively expensive as compared to when one package is used.

Furthermore, in the configuration described above, the orthogonality of the detection axes between the sensor devices more or less depends on the accuracy of installation of each sensor device (the accuracy of the mounting angle of each package) in the target apparatus.

In addition, also in a sensor device that responds to one detection axis, depending on the type of sensor element, it is necessary to dispose the principal surface so as to be orthogonal to the bottom face of the package or inclined relative to the bottom face of the package. Thus, there has been a demand for a new sensor element mounting structure.

Moreover, in the sensor device of Patent Document 1, the IC chip is firmly fixed to the supporting substrate and is electrically connected to the lead wiring section formed in the supporting substrate.

When a flexible wiring substrate, for example, is used as the lead wiring section, since the IC chip projects from the supporting substrate, there is a possibility that the wiring pattern of the flexible wiring substrate and an end of the IC chip make contact with each other and become shorted to one another due to bending of the flexible wiring substrate when the flexible wiring substrate is mounted across the IC chip and the supporting substrate.

### SUMMARY

An advantage of some aspects of the invention is to solve at least part of the problems described above, and the invention can be implemented as embodiments or application examples described below.

### Application Example 1

This application example is directed to a sensor module including: a supporting member having a first support face parallel to a first reference plane and a second support face parallel to a second reference plane which is orthogonal to the first reference plane or inclined relative to the first reference plane; an IC chip having connection terminals and external connection terminals on a side thereof where one face is located, the IC chip which is attached, on a side thereof where the other face along the one face is located, to at least one of the first support face and the second support face; a flexible wiring substrate attached to at least one of the external connection terminals of the IC chip; and a sensor element having connection electrodes, the connection electrodes being attached to the connection terminals of the IC chip, the sensor element being disposed on the side of the IC chip where the one face is located, the sensor element whose principal surface lies along a support face of the first support face and the second support face of the supporting member, the support face to which the IC chip is attached, wherein, on a face of the flexible wiring substrate, the face located on a side opposite to a side where the IC chip is located, a reinforcing section that improves the stiffness of the flexible wiring substrate is provided from an area in which the flexible wiring substrate is attached to the external connection terminals to an area over an end of the IC chip in a plan view.

With this configuration, in the sensor module, the IC chip is attached to the first support face and the second support face (hereinafter, the first support face, the second support face, and a third support face, which will be described later, will be also referred to simply as a support face or each support face) of the supporting member, the first support face and the second support face which are orthogonal to each other or inclined relative to each other, and the sensor element is attached to the side of the IC chip where the one face is located.

At this time, in the sensor module, since the principal surface of the sensor element is attached so as to lie along the support face to which the IC chip is attached, the principal surfaces of the sensor elements are orthogonal to one another or inclined relative to one another.

As a result, by being housed in one package, for example, the sensor module can provide a sensor device that responds to two axes.

Therefore, since the sensor module can considerably reduce the mounting space of a sensor device that responds to two axes as compared to an existing configuration in which two sensor devices, each responding to one axis, are used, it is possible to achieve further miniaturization of a target apparatus.

Moreover, since the sensor module can provide a sensor device that responds to two axes with one package, it is possible to reduce the cost related to the package as compared to an existing configuration in which two sensor devices, each responding to one axis, are used.

Furthermore, since the sensor module can provide a sensor device that responds to two axes with one package, it is possible to improve resistance to shock as compared to an existing configuration in which two sensor devices, each responding to one axis, are used and respond to two axes by changing the position in which the package is attached from the original position.

In addition, in the sensor module, the IC chip is attached to the support faces of the supporting member, the support faces which are orthogonal to each other or inclined relative to each other, and the sensor element is attached to the side of the IC chip where the one face is located in such a way that the principal surface lies along the support face of the supporting member.

As a result, since the orthogonality of the sensing axes is determined by the processing accuracy of the supporting member, the sensor module can eliminate dependence of the orthogonality of the sensing axes on the accuracy of installation of each sensor device (the accuracy of the mounting angle of each package) in the target apparatus as in the existing configuration.

Moreover, in the sensor module, the flexible wiring substrate is attached to the external connection terminals of the IC chip, and, on a face of the flexible wiring substrate, the face located on the side opposite to the side where the IC chip is located, the reinforcing section that improves the stiffness of the flexible wiring substrate is provided at least from an area in which the flexible wiring substrate is attached to the external connection terminals of the IC chip to an area over the end of the IC chip.

As a result, in the sensor module, the stiffness of the flexible wiring substrate is improved at least from an area in which the flexible wiring substrate is attached to the external connection terminals of the IC chip to an area over the end of the IC chip.

Therefore, when, for example, the sensor module is attached to an external member such as a package, a wiring pattern seldom makes contact with the end of the IC chip as a result of the flexible wiring substrate easily bending as described earlier, whereby a short circuit between the flexible wiring substrate and the IC chip can be prevented.

### Application Example 2

In the sensor module according to the application example described above, it is preferable that the supporting member have a third support face parallel to a third reference plane which is orthogonal to the first reference plane and the second reference plane or inclined relative to the first reference plane and the second reference plane, the IC chip be attached to the third support face, and the sensor element be disposed on the side of the IC chip where the one face is located and the connection electrodes be attached to the connection terminals of the IC chip in such a way that the principal surface lies along the third support face.

With this configuration, in the sensor module, the supporting member has the third support face in addition to the first support face and the second support face, the IC chip is attached to the third support face, and the sensor element is attached to the IC chip in such a way that the principal surface of the sensor element lies along the third support face.

As a result, by being housed in one package, for example, the sensor module can provide a sensor device that responds to three axes.

Therefore, since the sensor module can considerably reduce the mounting space of a sensor device that responds to three axes as compared to an existing configuration in which three sensor devices, each responding to one axis, are used, it is possible to achieve further miniaturization of a target apparatus.

Moreover, since the sensor module can provide a sensor device that responds to three axes with one package, it is possible to reduce the cost related to the package as compared to an existing configuration in which three sensor devices, each responding to one axis, are used.

Furthermore, since the sensor module can provide a sensor device that responds to three axes with one package, it is possible to improve resistance to shock as compared to an existing configuration in which three sensor devices, each responding to one axis, are used and respond to three axes by changing the position in which the package is attached from the original position.

### Application Example 3

In the sensor module according to the application example described above, it is preferable that the reinforcing section of the flexible wiring substrate contain metal.

As a result, in the sensor module, since the reinforcing section of the flexible wiring substrate contains metal, the reinforcing section can be formed by, for example, leaving part of a metal coating (for example, copper foil) for wiring of the flexible wiring substrate in the area described above.

Therefore, in the sensor module, the reinforcing section of the flexible wiring substrate can be provided in a rational manner.

### Application Example 4

In the sensor module according to the application example described above, it is preferable that the connection terminals of the IC chip be protrusion electrodes protruding toward the one face.

As a result, since the connection terminals of the IC chip are protrusion electrodes protruding toward the one face, the sensor module can provide clearance between the sensor element and the IC chip, making it possible to prevent contact between the sensor element and the IC chip reliably.

Therefore, the sensor module can stably drive the sensor element.

### Application Example 5

In the sensor module according to the application example described above, it is preferable that the IC chip be attached to two support faces of the first and second support faces and a third support face of the supporting member, the two support faces which are next to each other, the two support faces which are sides from which straight lines orthogonal to the two support faces extend so as to move away from each other.

With this configuration, since the IC chip is attached to two support faces of the support faces of the supporting member, the two support faces which are next to each other, the two support faces which are sides from which straight lines orthogonal to the two support faces extend so as to move away from each other, the sensor module can prevent the IC chip, the sensor element, and the flexible wiring substrate from interfering with one another even when the support faces come close to each other.

Therefore, since the sensor module allows the component elements to be disposed so as to be closer to one another, the sensor module can be further miniaturized.

### Application Example 6

In the sensor module according to the application example described above, it is preferable that, in at least one of the first and second support faces and a third support face, a hollow portion be provided.

With this configuration, since the hollow portion is provided in at least one of the support faces, by disposing the IC chip in the hollow portion, the sensor module allows the IC chip to be attached in a predetermined position of each support face accurately.

### Application Example 7

This application example is directed to a sensor device including the sensor module described in any one of the application examples described above and a package that houses the sensor module, and the sensor module is housed in the package.

With this configuration, since the sensor module described in any one of the application examples described above is housed in the package, the sensor device can provide a sensor device that can obtain the effects described in any one of the application examples described above.

### Application Example 8

This application example is directed to an electronic apparatus including the sensor module described in any one of the application examples described above.

With this configuration, since the electronic apparatus includes the sensor module described in any one of the application examples described above, the electronic apparatus can provide an electronic apparatus that can obtain the effects described in any one of the application examples described above.

### Application Example 9

This application example of the invention is directed to a method for producing a sensor device including: preparing a supporting member having a first support face parallel to a first reference plane and a second support face parallel to a second reference plane which is orthogonal to the first reference plane or inclined relative to the first reference plane or a supporting member having a first support face parallel to a first reference plane, a second support face parallel to a second reference plane which is orthogonal to the first reference plane or inclined relative to the first reference plane, and a third support face parallel to a third reference plane which is orthogonal to the first reference plane and the second reference plane or inclined relative to the first reference plane and the second reference plane; preparing an IC chip provided with one face and the other face lying along the one face, the IC chip having connection terminals and external connection terminals on a side thereof where the one face is located; preparing a sensor element having connection electrodes; preparing a plurality of flexible wiring substrates, at least one of which has, on a face thereof located on a side opposite to a side where the IC chip is located, a reinforcing section that improves stiffness, the reinforcing section being provided at least from an area in which the flexible wiring substrate is attached to the external connection terminals of the IC chip to an area over an end of the IC chip; preparing a package that houses the component elements; attaching the flexible wiring substrate to the external connection terminals of the IC chip; disposing the sensor element on a side of the IC chip where the one face is located and attaching the connection electrodes of the sensor element to the connection terminals of the IC chip in such a way that a principal surface of the sensor element lies along the one face or the other face; performing adjustment and characteristic inspection on the sensor element and the IC chip via the flexible wiring substrate; attaching a side of a sensor unit provided with the IC chip to which the sensor element and the flexible wiring substrate are attached, the side where the other face of the IC chip is located, to at least one of support faces of the first to third support faces of the supporting member, the support faces which are orthogonal to a supporting member joint surface of the package or inclined relative to the supporting member joint surface of the package; attaching the supporting member to which the sensor unit is attached to the supporting member joint surface of the package; attaching a side of another sensor unit to which the flexible wiring substrate provided with the reinforcing section is attached, the side where the other face of the IC chip is located, to a support face of the first to the third support faces of the supporting member attached to the supporting member joint surface of the package, the support face lying along the supporting member joint surface of the package; and attaching each flexible wiring substrate of each sensor unit to the supporting member joint surface of the package.

With the method for producing a sensor device, it is possible to produce and provide a sensor device that can obtain the effects described in Application Example 7 described above.

Moreover, in the method for producing a sensor device, the sensor unit is attached first to a support face of the support faces of the supporting member, the support face which is orthogonal to the supporting member joint surface of the package or inclined relative to the supporting member joint surface of the package.

As a result, with the method for producing a sensor device, since it is possible to hold the support face lying along the supporting member joint surface of the package with a suction apparatus, for example, the support face of the supporting member to which the sensor unit is attached later, the supporting member can be easily dealt with.

Therefore, since the method for producing a sensor device makes it easy to attach the supporting member to the package, the method can improve productivity.

### BRIEF DESCRIPTION OF THE DRAWINGS

The invention will be described with reference to the accompanying drawings, wherein like numbers reference like elements.

FIGS. 1A and 1B are schematic diagrams showing a schematic configuration of a sensor module of a first embodiment, FIG. 1A being a plan view of the sensor module of the first embodiment and FIG. 1B being a side view of the sensor module of the first embodiment viewed from the direction of an arrow A of FIG. 1A.

FIG. 2A is a side view of the sensor module of the first embodiment viewed from the direction of an arrow B of FIG. 1A, and FIG. 2B is a side view of the sensor module of the first embodiment viewed from the direction of an arrow C of FIG. 1A.

FIG. 3 is a sectional view of the sensor module of the first embodiment taken on the line D-D of FIG. 1A.

FIG. 4 is an enlarged plan view of a sensor element.

FIG. 5 is a schematic plan view explaining the movement of a vibrating gyro element.

FIGS. 6A and 6B are schematic plan views showing the detection vibration state of the vibrating gyro element.

FIG. 7 is an enlarged plan view showing the principal portions of the sensor module.

FIG. 8 is an enlarged sectional view showing the principal portions of the sensor module.

FIGS. 9A and 9B are schematic diagrams showing a schematic configuration of a gyro sensor of a second embodiment, FIG. 9A being a plan view of the gyro sensor of the second embodiment viewed from above from the lid's side and FIG. 9B being a sectional view of the gyro sensor of the second embodiment taken on the line J-J of FIG. 9A.

FIG. 10 is a flowchart showing production processes of the gyro sensor.

FIG. 11 is a schematic perspective view explaining a supporting member preparing process.

FIGS. 12A and 12B are schematic diagrams explaining a flexible wiring substrate joining process, FIG. 12A being a plan view and FIG. 12B being a side view.

FIGS. 13A and 13B are schematic diagrams explaining a vibrating gyro element joining process, FIG. 13A being a plan view and FIG. 13B being a side view.

FIGS. 14A and 14B are schematic diagrams explaining a sensor unit first joining process, FIG. 14A being a plan view and FIG. 14B being a side view from the direction of an arrow K of FIG. 14A.

FIGS. 15A and 15B are schematic diagrams explaining a supporting member joining process, FIG. 15A being a plan view and FIG. 15B being a sectional view taken on the line M-M of FIG. 15A.

FIGS. 16A and 16B are schematic diagrams explaining a sensor unit second joining process, FIG. 16A being a plan view and FIG. 16B being a sectional view taken on the line N-N of FIG. 16A.

### DESCRIPTION OF EXEMPLARY EMBODIMENTS

Hereinafter, embodiments of the invention will be described with reference to the drawings.

### First Embodiment

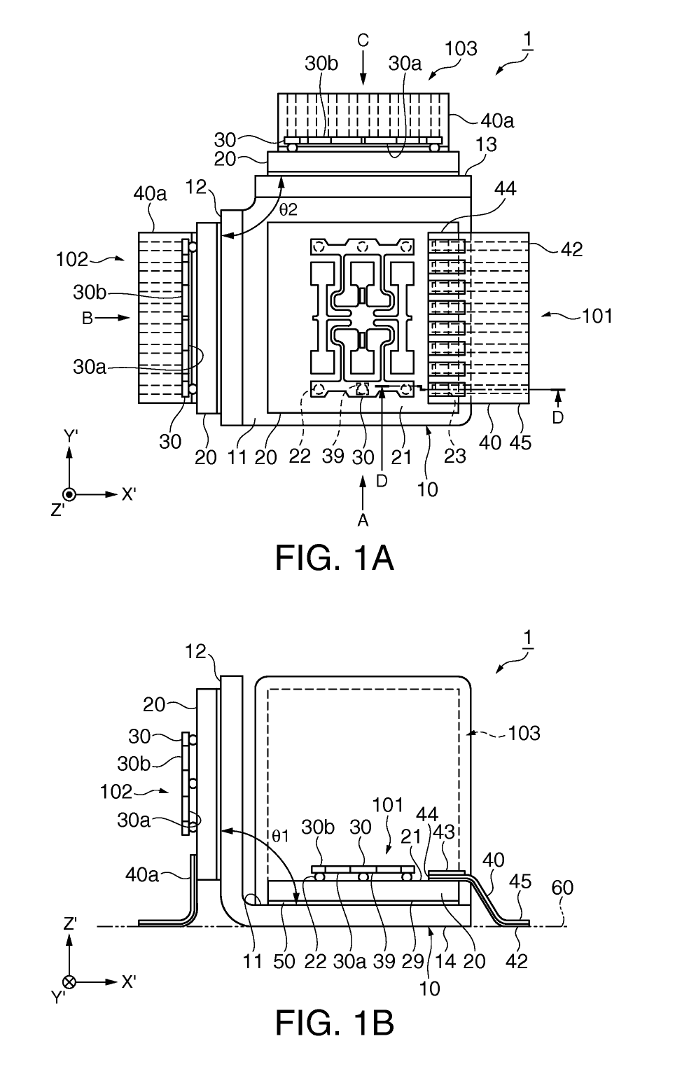

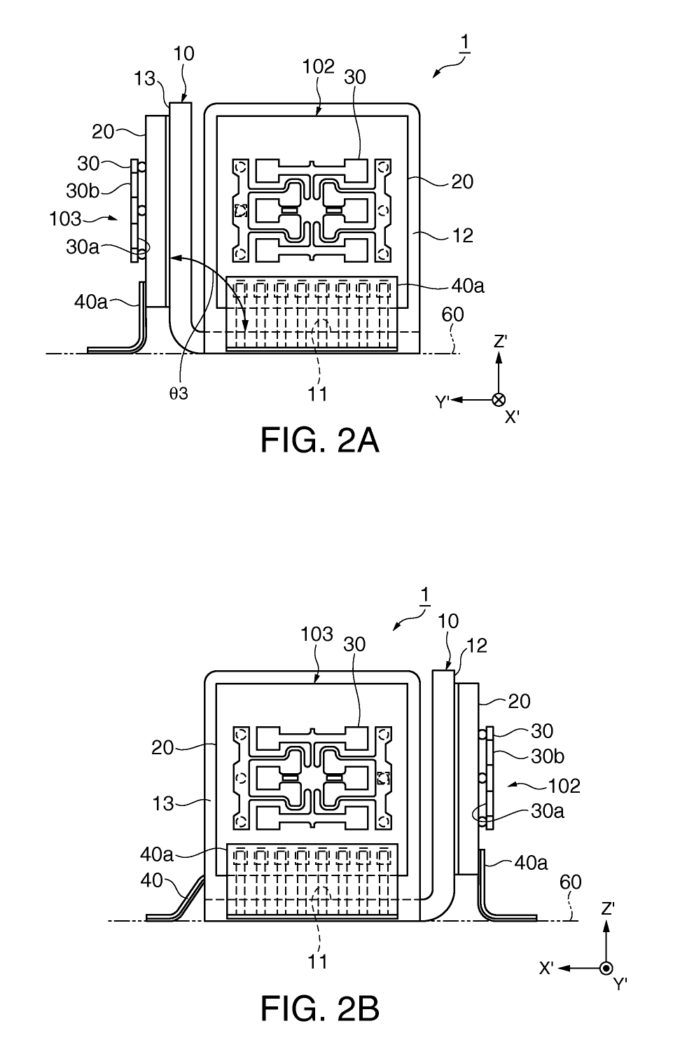

FIGS. 1A and 1B and FIGS. 2A and 2B are schematic diagrams showing a schematic configuration of a sensor module of a first embodiment. FIG. 1A is a plan view of the sensor module of the first embodiment, and FIG. 1B is a side view of the sensor module of the first embodiment viewed from the direction of an arrow A of FIG. 1A. FIG. 2A is a side view of the sensor module of the first embodiment viewed from the direction of an arrow B of FIG. 1A, and FIG. 2B is a side view of the sensor module of the first embodiment viewed from the direction of an arrow C of FIG. 1A.

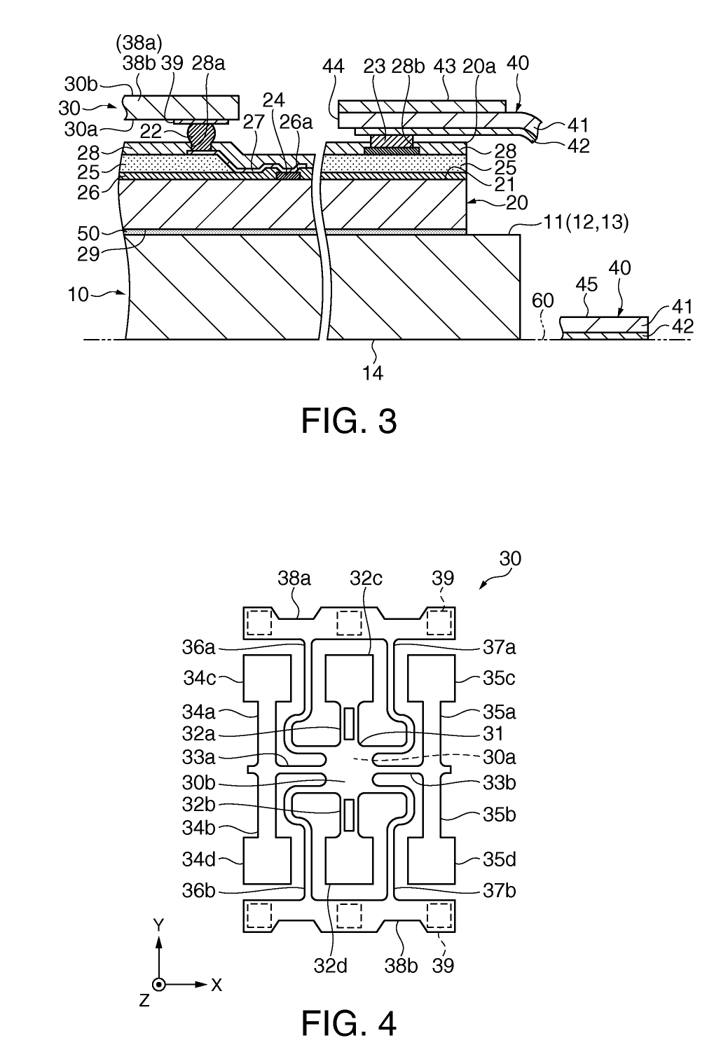

FIG. 3 is a sectional view of the sensor module of the first embodiment taken on the line D-D of FIG. 1A, and FIG. 4 is an enlarged plan view of a sensor element. Incidentally, the dimensional ratio of each component element in the drawings including drawings which will be described later is different from the actual dimensional ratio.

As shown in FIGS. 1A and 1B and FIGS. 2A and 2B, a sensor module 1 includes a supporting member 10, three IC chips 20, three vibrating gyro elements (gyro vibrating reeds) 30 as sensor elements, and two types of flexible wiring substrates 40 and 40a.

The supporting member 10 is made of metal such as structural steel, stainless steel, copper, brass, phosphor bronze, and nickel silver, and is formed by bending a flat plate whose planar shape is roughly a shape of an L (a shape of an inverted L) at two points at the right angle at a bent portion of the shape of an L in such a way that the bending directions intersect at right angles.

As a result, the supporting member 10 has a support face 11 as a first support face which is parallel to an unillustrated first reference plane, a support face 12 as a second support face which is parallel to an unillustrated second reference plane orthogonal to the first reference plane, and a support face 13 as a third support face which is parallel to an unillustrated third reference plane orthogonal to the first reference plane and the second reference plane.

In the supporting member 10, an angle θ1 which the support face 11 forms with the support face 12, an angle θ2 which the support face 12 forms with the support face 13, and an angle θ3 which the support face 11 forms with the support face 13 are 90 degrees (right angles). Incidentally, for the angles θ1 to θ3, a slight error (for example, about 0 to 2 degrees) is allowable if it does not affect the sensing function.

Incidentally, the support face 12 and the support face 13 are support faces which are next to each other and located on the sides from which a straight line orthogonal to the support face 12 and a straight line orthogonal to the support face 13 extend so as to move away from each other.

As shown in FIG. 3, each IC chip 20 has, on the side thereof where an active face 21 as one face is located, connection terminals 22 and external connection terminals 23.

In addition, the IC chips 20 each have a passive face 29 which is a face located on opposite side of the active face 21 and is the other face along the active face 21, the passive face 29 attached to each of the support faces 11, 12, and 13 of the supporting member 10 by an insulating adhesive 50 in a state in which the passive face 29 is insulated from the supporting member 10.

Specifically, on the side of the IC chip 20 where the active face 21 is located, an integrated circuit (not shown) including semiconductor devices such as a transistor and a memory element is formed. The integrated circuit is provided with a drive circuit for driving and vibrating the vibrating gyro element 30 and a detection circuit that detects detection vibration which is generated in the vibrating gyro element 30 when an angular velocity is applied thereto.

The IC chip 20 includes a first electrode 24 provided on the side of the IC chip 20 where the active face 21 is located, the connection terminals 22 provided on the side of the IC chip 20 where the active face 21 is located, the connection terminals 22 electrically connected to the first electrode 24, a stress relaxation layer 25 provided between the active face 21 and the connection terminals 22, and the external connection terminals 23 provided on the side of IC chip 20 where the active face 21 is located.

The first electrode 24 is formed in such a way that direct continuity is established between the first electrode 24 and the integrated circuit of the IC chip 20. Moreover, on the active face 21, a first insulating layer 26 serving as a passivation film is formed, and, in the first insulating layer 26, an opening 26a is formed on the first electrode 24.

With this configuration, the first electrode 24 is exposed to the outside in the opening 26a.

On the first insulating layer 26, the stress relaxation layer 25 formed of insulating resin is formed in a position other than positions in which the first electrode 24 and other electrodes are formed.

Moreover, to the first electrode 24, wiring 27 as rearrangement wiring is connected in the opening 26a of the first insulating layer 26. The wiring 27 is provided for performing rearrangement of the electrodes of the integrated circuit, and is formed so as to extend from the first electrode 24 disposed in a predetermined portion of the IC chip 20 and to be drawn further to an area on the stress relaxation layer 25.

Since the wiring 27 provides wiring between the first electrode 24 and the connection terminals 22 of the IC chip 20, the wiring 27 is generally called rearrangement wiring and is an important component element for increasing the flexibility of a connection position, in the IC chip 20, between the first electrode 24 on which severe position restrictions are imposed due to fine design and the vibrating gyro element 30 by arbitrarily shifting the positions of the connection terminals 22.

Moreover, on the side of the IC chip 20 where the active face 21 is located, a heat-resistant second insulating layer 28 formed of resin is formed in such a way as to cover the wiring 27, the stress relaxation layer 25, and the first insulating layer 26. Incidentally, the second insulating layer 28 may be a solder resist.

In the second insulating layer 28, an opening 28a is formed on the wiring 27 on the stress relaxation layer 25. With this configuration, part of the wiring 27 is exposed to the outside in the opening 28a.

In addition, on the exposed wiring 27 in the opening 28a, the connection terminals 22 are disposed. The connection terminals 22 are each formed as a protrusion electrode formed in the shape of a bump by using a solder ball, a gold wire, or an aluminum wire, for example. Here, as the connection terminal 22, a bump (for example, a resin core bump) formed by providing a metal film or a conductive adhesive on the surface of a resin protrusion can also be used. Moreover, electrical connection by the connection terminal 22 may be further secured by providing a conductive adhesive or the like on the surface of a metal bump.

With this configuration, the integrated circuit formed on the IC chip 20 is electrically connected to the vibrating gyro element 30 via the first electrode 24, the wiring 27, and the connection terminals 22.

At this time, in the sensor module 1, since the connection terminals 22 are each formed as a protrusion electrode, sufficient clearance is left between the vibrating gyro element 30 and the IC chip 20. This clearance provides a space for drive vibration and detection vibration of the vibrating gyro element 30.

Moreover, in the integrated circuit formed on the IC chip 20, in addition to the first electrode 24, another unillustrated electrode is formed. As is the case with the first electrode 24, the rearrangement wiring is connected to the other electrode, and the electrode is connected, in an opening 28b of the second insulating layer 28, to the external connection terminals 23 exposed to the outside.

The external connection terminals 23 are each formed as a protrusion electrode formed in the shape of a bump by using a solder ball, a gold wire, or an aluminum wire, for example, and, to the external connection terminals 23, the flexible wiring substrates 40 and 40a are attached.

The first electrode 24, the other electrode, and the rearrangement wiring such as the wiring 27 are formed of gold (Au), copper (Cu), silver (Ag), titanium (Ti), tungsten (W), titanium tungsten (TiW), titanium nitride (TiN), nickel (Ni), nickel vanadium (NiV), chromium (Cr), aluminum (Al), palladium (Pd), and the like.

Incidentally, the rearrangement wiring such as the wiring 27 may have not only a single-layer structure formed of one of the materials described above, but also a laminated structure formed by combining the materials described above. In addition, the rearrangement wiring such as the wiring 27 is usually formed in the same process and therefore formed of the same material.

Moreover, as the resin for forming the first insulating layer 26 and the second insulating layer 28, polyimide resin, silicone-modified polyimide resin, epoxy resin, silicone-modified epoxy resin, acrylic resin, phenolic resin, BCB (benzocyclobutene), and PBO (polybenzoxazole), for example, are used.

Incidentally, the first insulating layer 26 can also be formed of inorganic insulating materials such as silicon oxide (SiO₂) and silicon nitride (Si₃N₄) .

The passive face 29 of the IC chip 20 is attached to each of the support faces 11, 12, and 13 of the supporting member 10 by a polyimide, epoxy, or silicone insulating adhesive 50 in a state in which the passive face 29 is insulated therefrom.

Incidentally, in some drawings, for the sake of convenience, the second insulating layer 28 of the IC chip 20 is written as the active face 21.

As shown in FIG. 4, the vibrating gyro element 30 is formed by using crystal which is a piezoelectric material as a base material (a material forming a principal portion). The crystal has an X-axis called an electrical axis, a Y-axis called a mechanical axis, and a Z-axis called an optical axis.

In addition, the vibrating gyro element 30 is obtained by cutting crystal along a plane defined by the X-axis and the Y-axis intersecting at right angles at a crystal axis and processing the crystal so as to have a flat plate-like shape and has a predetermined thickness in a Z-axis direction orthogonal to the plane. Incidentally, the predetermined thickness is appropriately set in accordance with an oscillation frequency (a resonance frequency), an outer size, processability, and the like.

Moreover, for the flat plate forming the vibrating gyro element 30, an error in an angle at which the flat plate is cut from crystal, the error in each of the X-axis, the Y-axis, and the Z-axis, is allowable to some extent. For example, the flat plate which is cut from crystal at an angle in 0- to 7-degree range with respect to the X-axis can be used. The same goes for the Y-axis and the Z-axis.

The vibrating gyro element 30 is formed by etching (wet etching or dry etching) using photolithography. Incidentally, a plurality of vibrating gyro elements 30 can be produced from one crystal wafer.

The vibrating gyro element 30 has a configuration called double T-type.

The vibrating gyro element 30 includes a base 31 located in the center thereof, a pair of vibrating arms for detection 32a and 32b as vibrating sections, the pair of vibrating arms for detection 32a and 32b extending from the base 31 along the Y-axis, a pair of connecting arms 33a and 33b extending from the base 31 along the X-axis so as to be orthogonal to the vibrating arms for detection 32a and 32b, and a pair of vibrating arms for driving 34a and 34b and a pair of vibrating arms for driving 35a and 35b as vibrating sections, the pairs each extending from the tips of the connecting arms 33a and 33b along the Y-axis so as to be nearly parallel to the vibrating arms for detection 32a and 32b.

Moreover, the vibrating gyro element 30 includes supporting arms 36a, 36b, 37a, and 37b that extend from the base 31 roughly along the Y-axis through a space between the vibrating arms (for example, between the vibrating arm for detection 32a and the vibrating arm for driving 34a), a supporting section 38a provided across the tips of the supporting arms 36a and 37a extending in the same direction, and a supporting section 38b provided across the tips of the supporting arms 36b and 37b extending in the same direction.

The supporting sections 38a and 38b extend along the pair of connecting arms 33a and 33b so as to be located over the tips of the vibrating arms.

The supporting arms 36a, 36b, 37a, and 37b have the function of absorbing mechanical shock that causes false detection. The supporting arms 36a, 36b, 37a, and 37b have the function of absorbing mechanical shock by being deformed such as being warped or bent when mechanical shock that causes false detection is given to the vibrating gyro element 30. This makes it possible to prevent the mechanical shock that causes false detection from being transferred to the vibrating arms for driving 34a, 34b, 35a, and 35b and the vibrating arms for detection 32a and 32b.

Moreover, the vibrating gyro element 30 has unillustrated detection electrodes formed in the vibrating arms for detection 32a and 32b and unillustrated drive electrodes formed in the vibrating arms for driving 34a, 34b, 35a, and 35b.

In the vibrating gyro element 30, the vibrating arms for detection 32a and 32b form a detection vibration system detecting an angular velocity and the connecting arms 33a and 33b and the vibrating arms for driving 34a, 34b, 35a, and 35b form a drive vibration system driving the vibrating gyro element 30.

Furthermore, at the tips of the vibrating arms for detection 32a and 32b, weight sections 32c and 32d are formed, and, at the tips of the vibrating arms for driving 34a, 34b, 35a, and 35b, weight sections 34c, 34d, 35c, and 35d are formed.

This allows the vibrating gyro element 30 to achieve miniaturization and improvement of the sensitivity for detection of an angular velocity.

The vibrating gyro element 30 is disposed so as to overlap the IC chip 20 in a plan view on the side of the IC chip 20 where the active face 21 is located.

Incidentally, the principal surfaces of the vibrating gyro element 30 are front and back faces of the flat plate including the base 31, the vibrating arms, and the supporting sections. In this embodiment, a face which is electrically connected to the outside is referred to as one principal surface 30a, and a face facing in a direction opposite to a direction in which the one principal surface 30a faces (a face located on opposite side) is referred to as the other principal surface 30b.

On the one principal surface 30a of the supporting sections 38a and 38b of the vibrating gyro element 30, connection electrodes 39 drawn from the detection electrodes and the drive electrodes are provided.

As shown in FIG. 3, in the vibrating gyro element 30, the connection electrodes 39 are attached to the connection terminals 22 of the IC chip 20 (are electrically and mechanically connected to the connection terminals 22 of the IC chip 20) in such a way that the one principal surface 30a (the other principal surface 30b) lies along (is nearly parallel to) each of the support faces 11, 12, and 13 of the supporting member 10.

In other words, in the vibrating gyro element 30, the connection electrodes 39 are attached to the connection terminals 22 of the IC chip 20 (are electrically and mechanically connected to the connection terminals 22 of the IC chip 20) in such a way that the one principal surface 30a (the other principal surface 30b) lies along the active face 21 or the passive face 29 of the IC chip 20.

Here, the movement of the vibrating gyro element 30 of the sensor module 1 will be described.

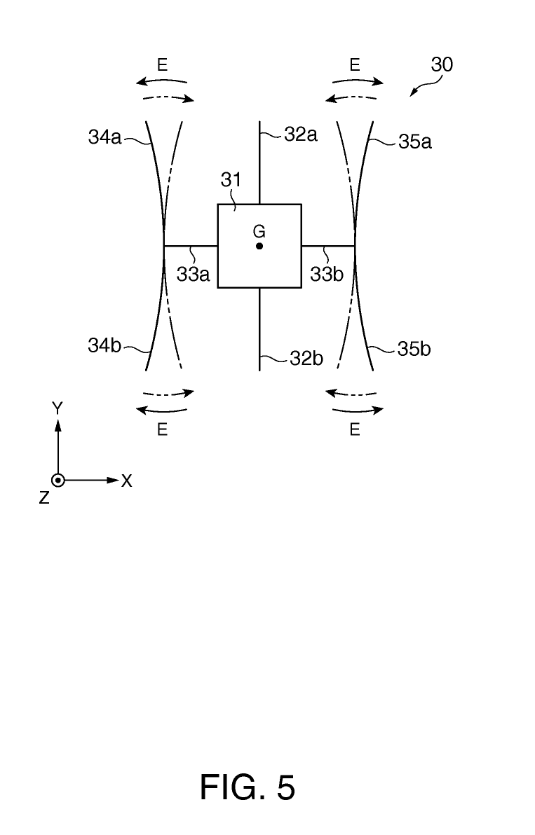

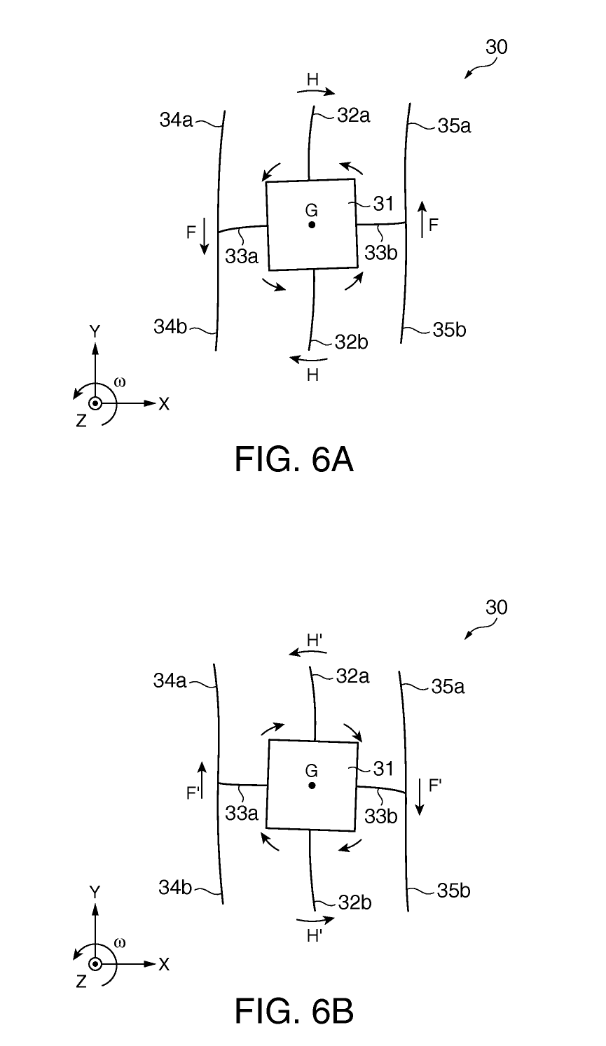

FIG. 5 and FIGS. 6A and 6B are schematic plan views explaining the movement of the vibrating gyro element. FIG. 5 shows a drive vibration state, and FIGS. 6A and 6B show a detection vibration state in a state in which an angular velocity is applied.

Incidentally, in FIG. 5 and FIGS. 6A and 6B, to describe the vibration state in a simplified form, the vibrating arms are depicted as lines, and the supporting arms and the supporting sections are omitted.

In FIG. 5, the drive vibration state of the vibrating gyro element 30 will be described.

First, as a result of a drive signal being applied from the integrated circuit (the drive circuit) of the IC chip 20, in the vibrating gyro element 30, the vibrating arms for driving 34a, 34b, 35a, and 35b vibrate while bending in the directions indicated by arrows E in a state in which no angular velocity is applied. In this bending vibration, vibration indicated by solid lines and vibration indicated by chain double-dashed lines are repeatedly performed at a predetermined frequency.

Next, in a state in which the above drive vibration is performed, when an angular velocity ω about the Z-axis is applied to the vibrating gyro element 30, the vibrating gyro element 30 performs vibration as shown in FIGS. 6A and 6B.

First, as shown in FIG. 6A, the Coriolis force in the directions of arrows F acts on the vibrating arms for driving 34a, 34b, 35a, and 35b and the connecting arms 33a and 33b forming the drive vibration system. At the same time, the vibrating arms for detection 32a and 32b are deformed in the directions of arrows H in response to the Coriolis force in the directions of arrows F.

Then, as shown in FIG. 6B, a force which makes the vibrating arms for driving 34a, 34b, 35a, and 35b and the connecting arms 33a and 33b return in the directions of arrows F′ acts on the vibrating arms for driving 34a, 34b, 35a, and 35b and the connecting arms 33a and 33b. At the same time, the vibrating arms for detection 32a and 32b are deformed in the directions of arrows H′ in response to the force in the directions of arrows F′.

In the vibrating gyro element 30, a series of movements described above is alternately performed repeatedly, whereby new vibration is effected.

Incidentally, the vibrations in the directions of arrows F and F′ are vibrations in a circumferential direction with respect to a barycenter G. In the vibrating gyro element 30, the detection electrodes formed in the vibrating arms for detection 32a and 32b detect the distortion of the crystal caused by the vibration, whereby an angular velocity W about the Z-axis is obtained.

Back in FIG. 3, the flexible wiring substrate 40 includes a base layer 41 formed mainly of resin having flexibility such as polyimide and a wiring pattern layer 42 which is bonded to the base layer 41 and is formed mainly of copper foil which has been patterned so as to have an intended shape.

Then, in the flexible wiring substrate 40, on a face of the base layer 41, the face located on the side opposite to the side where the active face 21 of the IC chip 20 is located, a reinforcing layer 43 as a reinforcing section that improves the stiffness of the flexible wiring substrate 40 is provided at least from an area in which the flexible wiring substrate 40 is attached to the external connection terminals 23 of the IC chip 20 to an area over an end 20a of the IC chip 20.

The reinforcing layer 43 is provided in the shape of islands, each having a rectangular shape, in a position corresponding to (facing) each wiring pattern of the wiring pattern layer 42.

As is the case with the wiring pattern layer 42, the reinforcing layer 43 contains a metal coating (metal) formed mainly of copper foil.

That is, the reinforcing layer 43 can be provided by leaving, in an intended shape described above, a metal coating on one face of a double-sided flexible wiring substrate having a metal coating (for example, copper foil) on both sides.

As described above, the flexible wiring substrate 40 has a laminated structure including the base layer 41, the wiring pattern layer 42, and the reinforcing layer 43.

In the flexible wiring substrate 40, the wiring pattern layer 42 at one end 44 is attached (joined) to the external connection terminals 23 of the IC chip 20.

Incidentally, the flexible wiring substrate 40a is the flexible wiring substrate 40 from which the reinforcing layer 43 is removed.

Since the flexible wiring substrates 40 and 40a have flexibility, they can be bent freely in accordance with the degree of flexibility.

As a result, as shown in FIGS. 1A and 1B to FIG. 3, the flexible wiring substrates 40 and 40a can be placed so as to lie along a stage 60 (an external member) on which the supporting member 10 is put by using an opposite face 14 located on the side opposite to the support face 11 by bending the flexible wiring substrates 40 and 40a at the middle thereof irrespective of the position of the IC chip 20.

At this time, since the flexible wiring substrate 40 includes the reinforcing layer 43, the stiffness of this portion is improved, whereby a contact between the wiring pattern layer 42 and the end 20a of the IC chip 20 seldom occurs when the flexible wiring substrate 40 is bent toward the passive face 29 of the IC chip 20 as shown in FIG. 3.

It is preferable that the reinforcing layer 43 provided on the flexible wiring substrate 40 be formed of a material having a larger Young's modulus than that of the material of the base layer 41 of the flexible wiring substrate 40. This makes it possible to prevent the flexible wiring substrate 40 from being warped toward the IC chip 20 more effectively.

Incidentally, the flexible wiring substrates 40 and 40a may be formed in such a way that a pitch between the wiring patterns of the wiring pattern layer 42 at the other end 45 is wider than a pitch between the wiring patterns of the wiring pattern layer 42 at the side of the IC chip 20 (at the one end 44).

Moreover, the flexible wiring substrates 40 and 40a may include a protecting layer that partially covers the wiring pattern layer 42 and thereby isolates and protects the wiring pattern layer 42 from the outside.

In this embodiment, the IC chip 20 to which the vibrating gyro element 30 and the flexible wiring substrates 40 and 40a are attached is called a sensor unit.

In other words, the sensor unit is provided with the IC chip 20 to which the vibrating gyro element 30 and the flexible wiring substrates 40 and 40a are attached.

In addition, the sensor unit attached to the support face 11 of the supporting member 10 is written as a sensor unit 101, the sensor unit attached to the support face 12 is written as a sensor unit 102, and the sensor unit attached to the support face 13 is written as a sensor unit 103.

Incidentally, the flexible wiring substrate 40 is used in the sensor unit 101, and the flexible wiring substrate 40a is used in the sensor unit 102 and the sensor unit 103.

Back in FIGS. 1A and 1B and FIGS. 2A and 2B, an X′-axis, a Y′-axis, and a Z′-axis are axes which are orthogonal to one another. In addition, the support face 11 of the supporting member 10 is orthogonal to the Z′-axis, the support face 12 is orthogonal to the X′-axis, and the support face 13 is orthogonal to the Y′-axis.

As a result, the sensor unit 101 attached to the support face 11 can detect an angular velocity with respect to the Z′-axis because the one principal surface 30a (the other principal surface 30b) of the vibrating gyro element 30 is orthogonal to the Z′-axis.

Similarly, the sensor unit 102 attached to the support face 12 can detect an angular velocity with respect to the X′-axis because the one principal surface 30a (the other principal surface 30b) of the vibrating gyro element 30 is orthogonal to the X′-axis.

Moreover, similarly, the sensor unit 103 attached to the support face 13 can detect an angular velocity with respect to the Y′-axis because the one principal surface 30a (the other principal surface 30b) of the vibrating gyro element 30 is orthogonal to the Y′-axis.

Therefore, the sensor module 1 provided with the sensor units 101, 102, and 103 can detect the angular velocities with respect to the three axes: the X′-axis, the Y′-axis, and the Z′-axis which are orthogonal to one another.

As described above, in the sensor module 1 of the first embodiment, the IC chips 20 are attached to the three support faces 11, 12, and 13 of the supporting member 10, the three support faces 11, 12, and 13 which are orthogonal to one another, and the vibrating gyro element 30 is attached to the side of each IC chip 20 where the active face 21 is located.

At this time, in the sensor module 1, since the one principal surface 30a (the other principal surface 30b) of the vibrating gyro element 30 is attached in such a way as to lie along each of the support faces 11, 12, and 13 of the supporting member 10, the one principal surfaces 30a (the other principal surfaces 30b) of the vibrating gyro elements 30 of the sensor units 101, 102, and 103 are orthogonal to the X′-axis, the Y′-axis, and the Z′-axis which are orthogonal to one another.

Thus, by being housed in one package, for example, the sensor module 1 can provide a sensor device (a gyro sensor) that responds to three axes.

Therefore, since the sensor module 1 can considerably reduce the mounting space of the sensor device that responds to three axes as compared to an existing configuration in which three sensor devices, each responding to one axis, are used, it is possible to achieve further miniaturization of a target apparatus.

Moreover, since the sensor module 1 can provide a sensor device that responds to three axes with one package, it is possible to reduce the cost related to the package as compared to an existing configuration in which three sensor devices, each responding to one axis, are used.

Furthermore, since the sensor module 1 can provide a sensor device that responds to three axes with one package, it is possible to improve resistance to shock as compared to an existing configuration in which a plurality of sensor devices, each responding to one axis, are used and respond to three axes by changing the position in which the package is attached from the original position.

In addition, in the sensor module 1, the IC chips 20 are attached to the three support faces 11, 12, and 13 of the supporting member 10, the three support faces 11, 12, and 13 which are orthogonal to one another, and the one principal surface 30a (the other principal surface 30b) of the vibrating gyro element 30 is attached on the side of each IC chip 20 where the active face 21 is located in such a way as to lie along each of the support faces 11, 12, and 13.

As a result, since the orthogonality of the sensing axes (the X′-axis, the Y′-axis, and the Z′-axis) is determined by the processing accuracy (the accuracy of the angles θ1, θ2, θ3) of the supporting member 10, the sensor module 1 can eliminate dependence of the orthogonality of the sensing axes on the accuracy of installation of each sensor device (the accuracy of the mounting angle of the package) in the target apparatus as in the existing configuration.

Moreover, since the flexible wiring substrates 40 and 40a have flexibility, the sensor module 1 can bring the flexible wiring substrates 40 and 40a partially into a horizontal state by bending the flexible wiring substrates 40 and 40a irrespective of the position of each IC chip 20.

Thus, for example, the sensor module 1 can be easily attached to an external member such as a package and allows a characteristic inspection or the like to be easily performed on the IC chips 20 and the vibrating gyro elements 30 via the flexible wiring substrates 40 and 40a in a horizontal state.

As a result, the sensor module 1 can improve the productivity.

Furthermore, the sensor module 1 may be formed in such a way that a pitch between the wiring patterns of the wiring pattern layer 42 of the flexible wiring substrates 40 and 40a at the other end 45 is wider than a pitch between the wiring patterns of the wiring pattern layer 42 at the side of the IC chip 20 (at the one end 44).

Thus, the sensor module 1 allows adjustment and characteristic inspection to be easily performed on the vibrating gyro elements 30 and the IC chips 20 by bringing a probe into contact with the wiring pattern layer 42 and can be easily attached to the external member such as a package.

As a result, the sensor module 1 can improve the productivity.

Moreover, in the sensor module 1, the flexible wiring substrate 40 is attached to the external connection terminals 23 of the IC chip 20 of the sensor unit 101, and, on a face of the flexible wiring substrate 40, the face located on the side opposite to the side where the active face 21 of the IC chip 20 is located, the reinforcing layer 43 that improves the stiffness is provided at least from an area in which the flexible wiring substrate 40 is attached to the external connection terminals 23 of the IC chip 20 to an area over the end 20a of the IC chip 20.

As a result, in the sensor module 1, the stiffness of the flexible wiring substrate 40 is improved at least from an area in which the flexible wiring substrate 40 is attached to the external connection terminals 23 of the IC chip 20 to an area over the end 20a of the IC chip 20.

Therefore, when, for example, the sensor module 1 is attached to the external member such as a package, the flexible wiring substrate 40 seldom makes contact with the end 20a of the IC chip 20 as a result of the flexible wiring substrate 40 easily bending as described earlier.

As a result, the sensor module 1 can prevent a short circuit between the wiring pattern layer 42 of the flexible wiring substrate 40 and the IC chip 20 due to contact between the flexible wiring substrate 40 and the IC chip 20 and a short circuit between the wiring patterns of the wiring pattern layer 42 via the IC chip 20 when, for example, the active face 21 is exposed at the end 20a of the IC chip 20.

Furthermore, in the sensor module 1, since the reinforcing layer 43 of the flexible wiring substrate 40 is a metal coating, the reinforcing layer 43 can be formed by, for example, leaving part of one metal coating (copper foil) of a double-sided flexible wiring substrate so as to have the shape described above.

As a result, the sensor module 1 does not always have to prepare a new additional member and can provide the reinforcing layer 43 of the flexible wiring substrate 40 in a rational manner.

Moreover, since the connection terminals 22 of the IC chip 20 are each a protrusion electrode protruding toward the active face 21, the sensor module 1 can provide clearance between the vibrating gyro element 30 and the IC chip 20, making it possible to prevent contact between the vibrating gyro element 30 and the IC chip 20.

As a result, the sensor module 1 can stably drive the vibrating gyro element 30.

Furthermore, in the sensor module 1, the support face 12 and the support face 13 of the supporting member 10 are support faces which are next to each other, the support faces which are sides from which a straight line orthogonal to the support face 12 and a straight line orthogonal to the support face 13 extend so as to move away from each other.

As a result, even when the support faces 12 and 13 come close to each other, the sensor module 1 can prevent the IC chips 20, the vibrating gyro elements 30, and the flexible wiring substrates 40a which are attached to the support faces 12 and 13 from interfering with one another.

Therefore, since the sensor module 1 allows the component elements to be disposed so as to be closer to one another, the sensor module 1 can be further miniaturized.

Furthermore, even when an electric conductor is used as the material of the supporting member 10 or an insulator is used as a base material of the supporting member 10, by forming a coating of conductive material on the surface of the supporting member 10, it is possible to prevent unnecessary capacitive coupling of the IC chip 20 and the vibrating gyro element 30 between the different detection axes. That is, the shielding effect of the supporting member 10 can reduce unnecessary capacitive coupling between the sensor units 101, 102, and 103.

In addition, since wiring can be installed on the flexible wiring substrate 40a more simply than when the sensor units 102 and 103 are attached to the opposite face (the rear face) of the support face 12 and the opposite face (the rear face) of the support face 13, the sensor module 1 allows the flexible wiring substrate 40a to be easily attached to the external member such as a package.

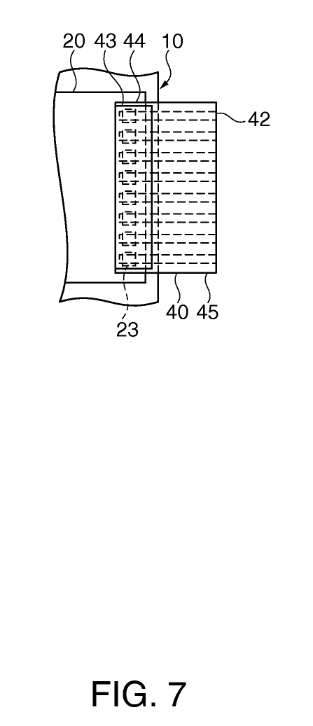

Incidentally, in the sensor module 1, as shown in FIG. 7 which is an enlarged plan view showing the principal portions, the reinforcing layer 43 of the flexible wiring substrate 40 may have a virtually rectangular shape which lies across the wiring patterns of the wiring pattern layer 42.

The planar shape of the reinforcing layer 43 of the flexible wiring substrate 40 maybe appropriately selected from the shapes including the shape of this embodiment in accordance with intended stiffness.

Incidentally, in place of the flexible wiring substrate 40a, the sensor module 1 may use the flexible wiring substrate 40 with the reinforcing layer 43 in the sensor units 102 and 103.

In this case, by using the flexible wiring substrate 40 in the sensor units 102 and 103 in place of the flexible wiring substrate 40a, the sensor module 1 can prevent a possible short circuit between the flexible wiring substrate 40a and IC chip 20 which is caused as a result of the flexible wiring substrate 40a bending toward the IC chip 20.

Incidentally, in the sensor module 1, the reinforcing layer 43 of the flexible wiring substrate 40 may be formed as a member containing resin such as polyimide resin and epoxy resin.

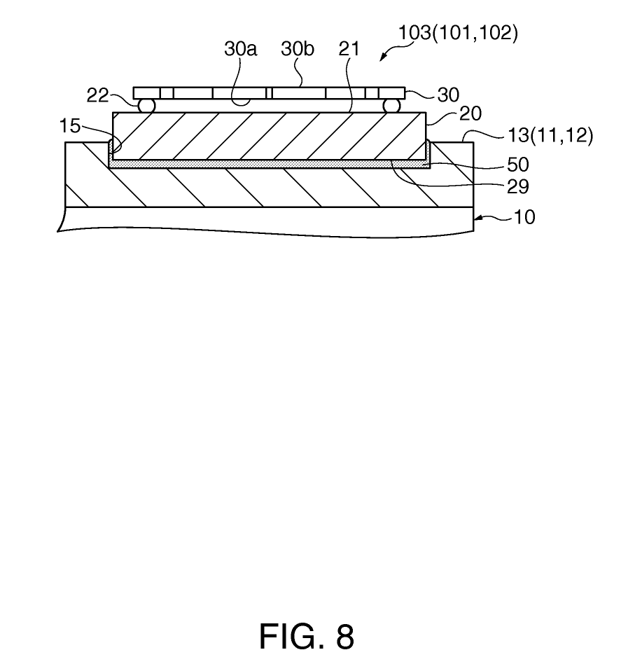

In addition, in the sensor module 1, as shown in FIG. 8 which is an enlarged sectional view showing the principal portions, a hollow portion 15 may be provided in the support faces 11, 12, and 13 of the supporting member 10.

In this case, by disposing the IC chips 20 in the hollow portions 15, the sensor module 1 allows the IC chips 20 to be attached in predetermined positions of the support faces 11, 12, and 13 accurately.

Incidentally, it is preferable that the hollow portions 15 be shaped so as to surround the IC chips 20 entirely when viewed from the directions of the normals of the support faces 11, 12, and 13. However, the hollow portions 15 may each have a shape by which one side of the IC chip 20 is unenclosed.

In addition, the sensor module 1 can have a configuration in which the sensor unit 102 is attached to the support face 12 orthogonal to a joint surface (an opposite face 14) at which the sensor module 1 is joined to the package (the external member) and the sensor units 101 and 103 are removed. Alternatively, the sensor module 1 can have a configuration in which the sensor unit 103 is attached to the support face 13 and the sensor units 101 and 102 are removed.

With these configurations, the sensor module 1 can provide a reliable mounting structure of a sensor element in a sensor device that responds to one axis and is installed in such a way that the principal surface of the sensor element (the vibrating gyro element 30) is orthogonal to the bottom face of the package.

Incidentally, the sensor module 1 may have a configuration in which any one of the sensor units 101, 102, and 103 is removed and the angular velocities with respect to two axes orthogonal to each other are detected. In this case, the supporting member 10 may have an L-shaped angle shape.

Moreover, in the sensor module 1, the supporting member 10 may be formed as not a product obtained by bending a flat plate but a rectangular parallelepiped or a cube.

Incidentally, the sensor module 1 may have a configuration in which, by providing the connection electrodes 39 of the vibrating gyro element 30 in one principal surface 30a of the base 31, the supporting arms 36a, 36b, 37a, and 37b and the supporting sections 38a and 38b of the vibrating gyro element 30 are removed.

With this configuration, the sensor module 1 can make the planar size of the IC chip 20 smaller than the planar size of the vibrating gyro element 30.

Moreover, the sensor module 1 may have a configuration in which the support faces 11, 12, and 13 are not orthogonal to one another (are inclined) due to the characteristics of a sensor element and the angles θ1, θ2, and θ3 are acute angles or obtuse angles.

### Second Embodiment

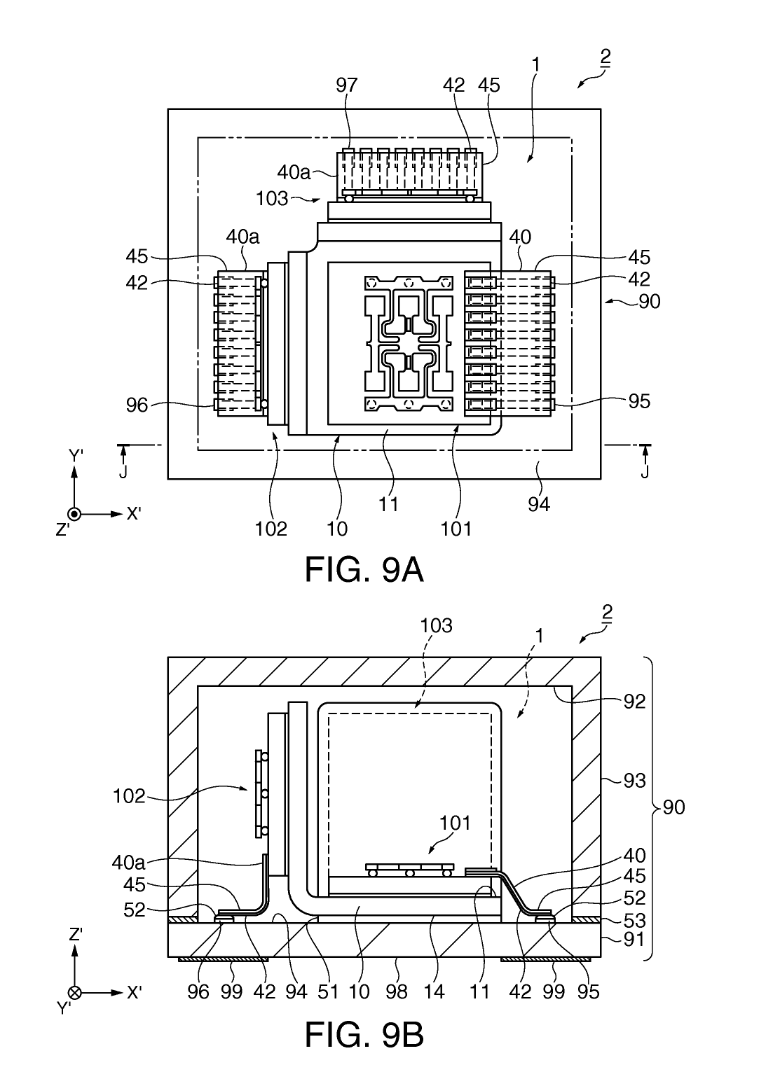

FIGS. 9A and 9B are schematic diagrams showing a schematic configuration of a gyro sensor as a sensor device of a second embodiment. FIG. 9A is a plan view of the gyro sensor of the second embodiment viewed from above from the lid's side, and FIG. 9B is a sectional view of the gyro sensor of the second embodiment taken on the line J-J of FIG. 9A.

Incidentally, in a plan view, the lid is omitted for the sake of convenience, and the shape of an inner wall of the lid is indicated by a chain double-dashed line.

Moreover, such portions as are common to the first embodiment described above are identified with the same reference numerals, and their explanations will be omitted. In the following description, only differences from the first embodiment described above will be explained.

As shown in FIGS. 9A and 9B, a gyro sensor 2 has a sensor module 1 and a package 90 that houses the sensor module 1, and the sensor module 1 is disposed and housed in the package 90.

The package 90 is formed of a rectangular flat plate-like package base 91, a lid 93 having a hollow portion 92 and covering the package base 91, and the like.

As the package base 91, an aluminum oxide sintered compact formed by molding a ceramic green sheet and sintering the molded ceramic green sheet, crystal, glass, or the like is used.

As the lid 93, the same material as the material of the package base 91 or metal such as Kovar, 42 alloy, and stainless steel is used.

On a top face 94 (a face covered with the lid 93) of the package base 91, internal terminals 95, 96, and 97 are provided in positions corresponding to flexible wiring substrates 40 and 40a of sensor units 101, 102, and 103 of the sensor module 1.

On a lower face 98 (a face which is a bottom face of the package 90 and is located along the top face 94) of the package base 91, a plurality of external terminals 99 are provided, the external terminals 99 which are used when the package is installed in an external device (an external member) or the like.

The internal terminals 95, 96, and 97 are connected to the external terminals 99 via unillustrated internal wiring.

The internal terminals 95, 96, and 97 and the external terminals 99 are formed of, for example, a metal coating formed by stacking coatings of nickel (Ni), gold (Au), and the like on a metallized layer such as tungsten (W) by plating.

Incidentally, the package may be formed of a package base having a hollow portion and a flat plate-like lid that covers the package base. Moreover, the package may have a hollow portion in both the package base and the lid.

The sensor module 1 is placed on the top face 94 of the package base 91, and an opposite face 14 (a rear face) of a support face 11 is attached to the top face 94 by a joining member 51 such as an adhesive.

In addition, in the sensor module 1, a wiring pattern layer 42 at the other end 45 in the flexible wiring substrate 40 of the sensor unit 101 is attached to the internal terminal 95 of the package base 91 by a joining member 52 having conductive properties such as a conductive adhesive, an anisotropic conductive film, or solder.

Similarly, in the sensor module 1, a wiring pattern layer 42 at the other end 45 in the flexible wiring substrate 40a of the sensor unit 102 is attached to the internal terminal 96 of the package base 91 by the joining member 52.

Moreover, similarly, in the sensor module 1, a wiring pattern layer 42 at the other end 45 in the flexible wiring substrate 40a of the sensor unit 103 is attached to the internal terminal 97 of the package base 91 by the joining member 52.

As a result, in the gyro sensor 2, the sensor units 101, 102, and 103 of the sensor module 1, the internal terminals 95, 96, and 97, and the external terminals 99 are electrically connected to one another.

In the gyro sensor 2, the package base 91 is covered with the lid 93 in a state in which the sensor module 1 is attached to the top face 94 of the package base 91 in the manner as described above, and the lid 93 is attached to the package base 91 by a joining member 53 such as a seam ring, low-melting glass, or an adhesive, whereby the package 90 is hermetically sealed.

Incidentally, it is preferable that the inside of the package 90 be maintained under vacuum (in a state with a high degree of vacuum) so that the vibrations of the vibrating gyro elements 30 of the sensor units 101, 102, and 103 are not hampered.

Since the gyro sensor 2 has, in the package 90, the sensor module 1 that detects the angular velocities with respect to three axes: an X′-axis, a Y′-axis, and a Z′-axis which are orthogonal to one another, the gyro sensor 2 is a gyro sensor that responds to three axes.

As a result, the gyro sensor 2 is used for, for example, hand movement correction of an imaging device and position detection and position control of a vehicle or the like in a movable body navigation system using a GPS (global positioning system) satellite signal.

Here, an example of a method for producing the gyro sensor 2 will be described.

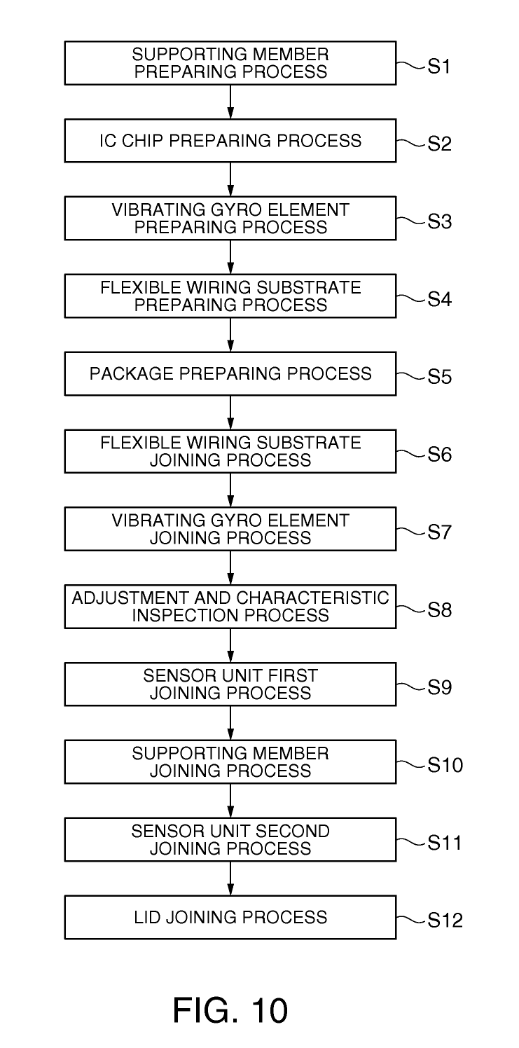

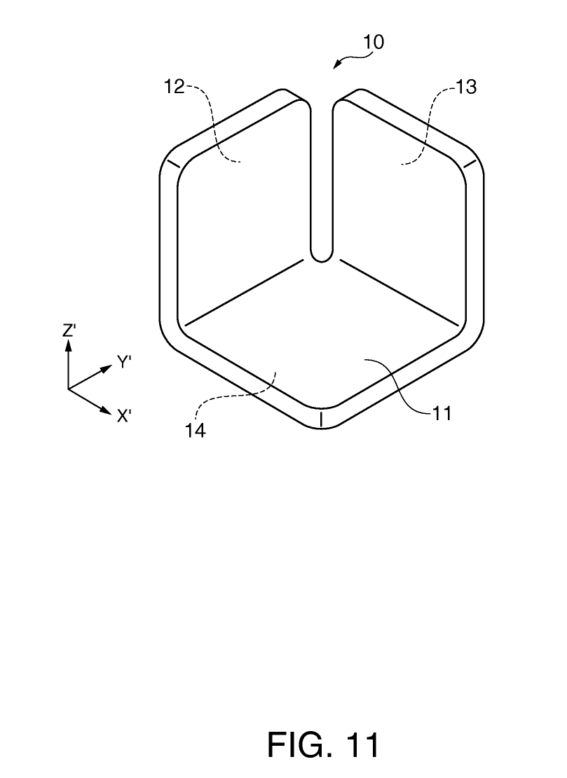

FIG. 10 is a flowchart showing production processes of the gyro sensor, and FIG. 11 to FIGS. 16A and 16B are schematic diagrams explaining principal production processes.

As shown in FIG. 10, the method for producing the gyro sensor 2 includes a supporting member preparing process S1, an IC chip preparing process S2, a vibrating gyro element preparing process S3, a flexible wiring substrate preparing process S4, a package preparing process S5, a flexible wiring substrate joining process S6, a vibrating gyro element joining process S7, an adjustment and characteristic inspection process S8, a sensor unit first joining process S9, a supporting member joining process S10, a sensor unit second joining process S11, and a lid joining process S12.

Supporting member preparing process S1

First, as shown in FIG. 11, a supporting member 10 having three support faces 11, 12, and 13 which are orthogonal to one another, the support faces 11, 12, and 13 which have been described earlier, is prepared.

IC Chip Preparing Process S2

Then, IC chips 20 each having, on the side thereof where an active face 21 is located, connection terminals 22 and external connection terminals 23 are prepared (see FIGS. 1A and 1B and FIG. 3).

Vibrating Gyro Element Preparing Process S3

Then, vibrating gyro elements 30 each having a base 31, vibrating arms (32a and the like) extending from the base 31, and connection electrodes 39 provided in supporting sections 38a and 38b, which are shown in FIG. 4, are prepared.

Flexible Wiring Substrate Preparing Process S4

Then, flexible wiring substrates 40 and 40a having flexibility are prepared (see FIGS. 1A and 1B and FIG. 3). Incidentally, as described earlier, in the flexible wiring substrate 40, a reinforcing layer 43 that improves stiffness is provided at least from an area in which the flexible wiring substrate 40 is attached to the external connection terminals 23 of the IC chip 20 to an area over an end 20a of the IC chip 20.

Package Preparing Process S5

Then, a package 90 (a package base 91, a lid 93, and the like) that houses the component elements described above is prepared (see FIG. 8).

Incidentally, the order of the preparing processes S1 to S5 is not limited to the order described above, and the preparing processes S1 to S5 are not in particular order.

Flexible Wiring Substrate Joining Process S6

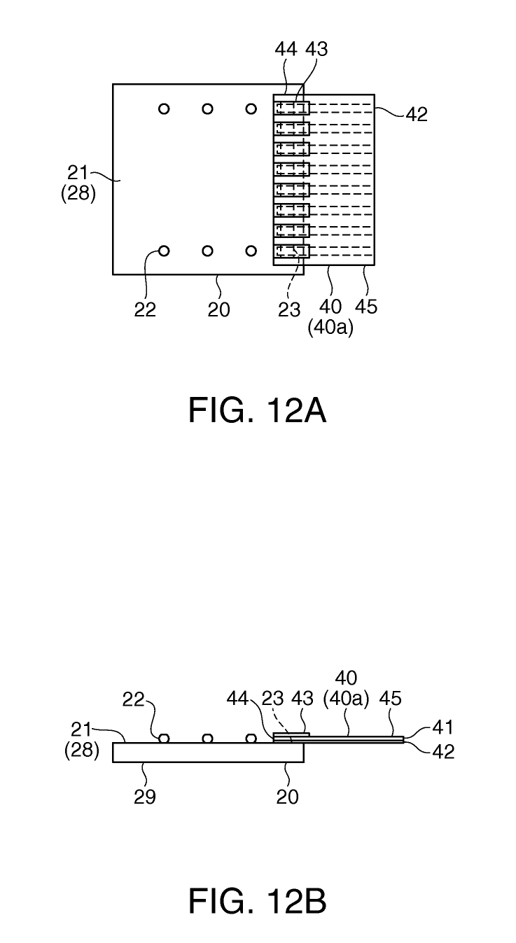

Then, as shown in FIGS. 12A and 12B, the wiring pattern layers 42 at one ends 44 of the flexible wiring substrates 40 and 40a are attached (joined) to the external connection terminals 23 of the IC chips 20 by an ultrasonic joining method, a hot pressure joining method, or the like (for the details of the joined portions, see FIG. 3).

Incidentally, in FIGS. 12A and 12B, the flexible wiring substrates 40 and 40a are placed on the IC chips 20 and attached thereto. However, it is also possible to place the inverted flexible wiring substrates 40 and 40a on a stage (a working table), place the inverted IC chips 20 on the flexible wiring substrates 40 and 40a, and attach the external connection terminals 23 of the IC chips 20 to the wiring pattern layers 42 of the flexible wiring substrates 40 and 40a.

Vibrating Gyro Element Joining Process S7

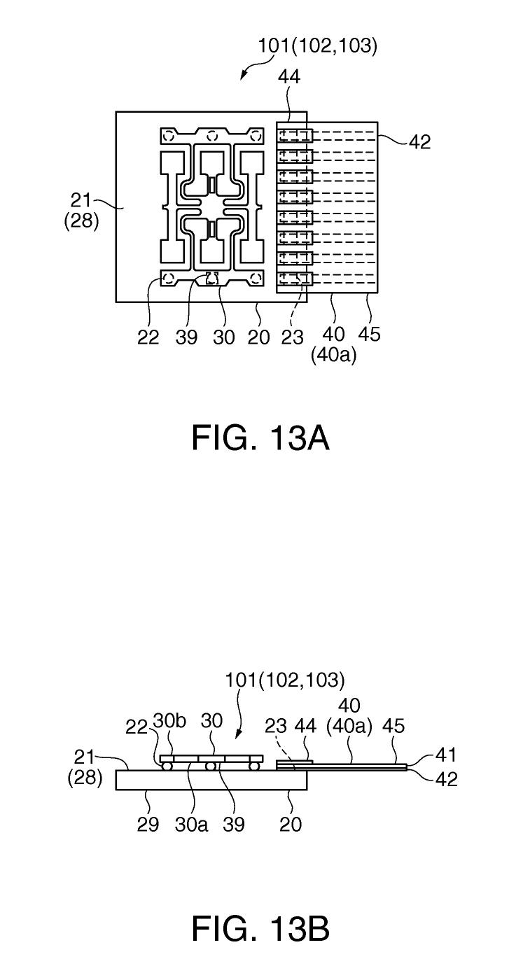

Then, as shown in FIGS. 13A and 13B, the vibrating gyro element 30 is placed on the side of each IC chip 20 where the active face 21 (a second insulating layer 28) is located, and the connection electrodes 39 of the vibrating gyro element 30 are attached (joined) to the connection terminals 22 of each IC chip 20 in such a way that one principal surface 30a (the other principal surface 30b) of the vibrating gyro element 30 lies along (is nearly parallel to) the active face 21 (the second insulating layer 28) or a passive face 29 (for the details of the joined portions, see FIG. 3).

As a result, sensor units 101, 102, and 103 each having the IC chip 20 to which the vibrating gyro element 30 and the flexible wiring substrates 40 and 40a are attached are obtained.

Adjustment and Characteristic Inspection Process S8

Then, adjustment and characteristic inspection of the vibrating gyro elements 30 and the IC chips 20 are performed via the flexible wiring substrates 40 and 40a.

Specifically, the sensor units 101, 102, and 103 are set on an unillustrated adjustment apparatus and an unillustrated characteristic inspection apparatus, and adjustment work such as balance adjustment (balance tuning) by which the balance of the weights of the vibrating arms is achieved by removing the metal coatings of gold (Au), silver (Ag), chromium (Cr), and the like provided in the weight sections of the vibrating arms of the vibrating gyro elements 30 by illuminating the coatings with a laser and various kinds of characteristic inspections of the vibrating gyro elements 30 and the IC chips 20 are performed.

Sensor Unit First Joining Process S9

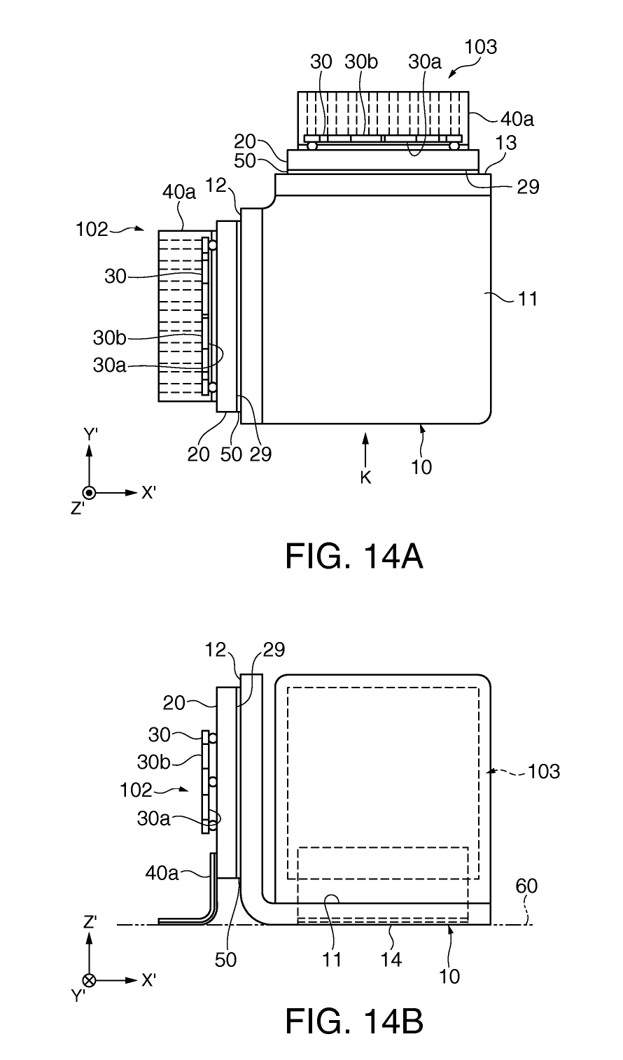

Then, as shown in FIGS. 14A and 14B, the sensor units 102 and 103 are attached (joined) to the support faces 12 and 13 of the supporting member 10.

Specifically, the sides of the IC chips 20 of the sensor units 102 and 103 where the passive faces 29 are located are attached, by the insulating adhesive 50, to the support faces 12 and 13 of the support faces 11, 12, and 13 in the supporting member 10 in a state in which they are insulated from the supporting member 10, the support faces 12 and 13 which are support faces orthogonal to a top face 94 of the package base 91 as a supporting member joint surface of the package 90.

That is, the sensor unit 102 is attached to the support face 12, and the sensor unit 103 is attached to the support face 13.

At this time, the one principal surfaces 30a (the other principal surfaces 30b) of the vibrating gyro elements 30 lie along the support faces 12 and 13.

Supporting Member Joining Process S10

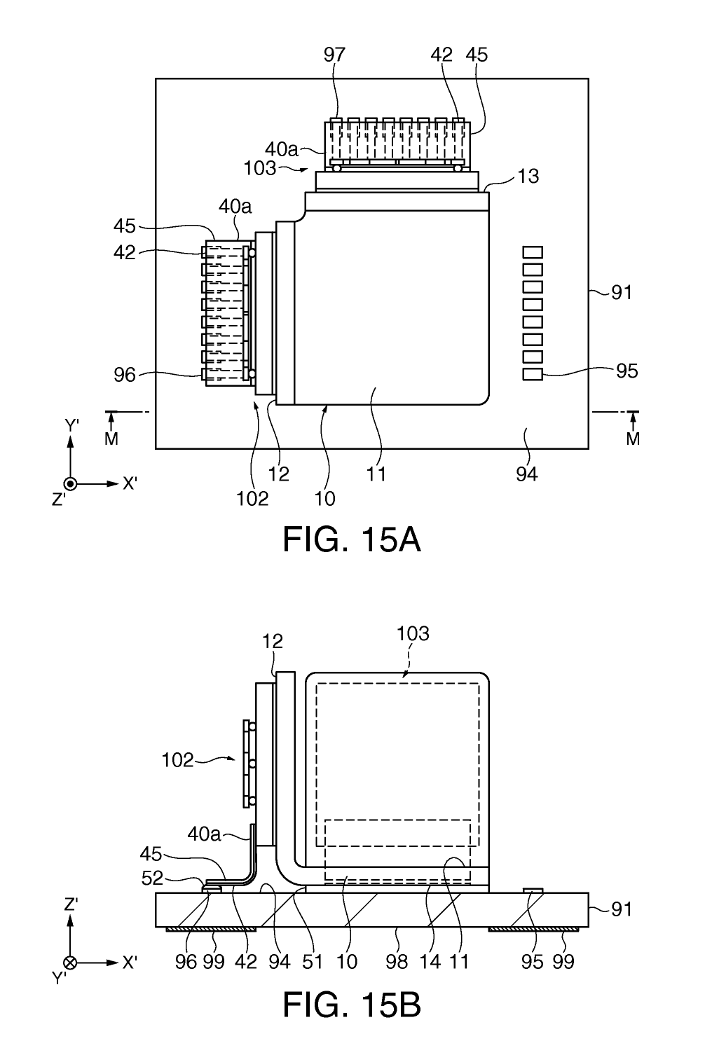

Then, as shown in FIGS. 15A and 15B, the supporting member 10 to which the sensor units 102 and 103 are attached is transported in a state in which the support face 11 lying along the top face 94 of the package base 91 is sucked in by an unillustrated suction apparatus, and the opposite face 14 of the support face 11 is attached to the top face 94 of the package base 91 by using the joining member 51.

Incidentally, it is preferable to use an adhesive having insulating properties as the joining member 51 from the viewpoint of preventing a short circuit.

Sensor Unit Second Joining Process S11

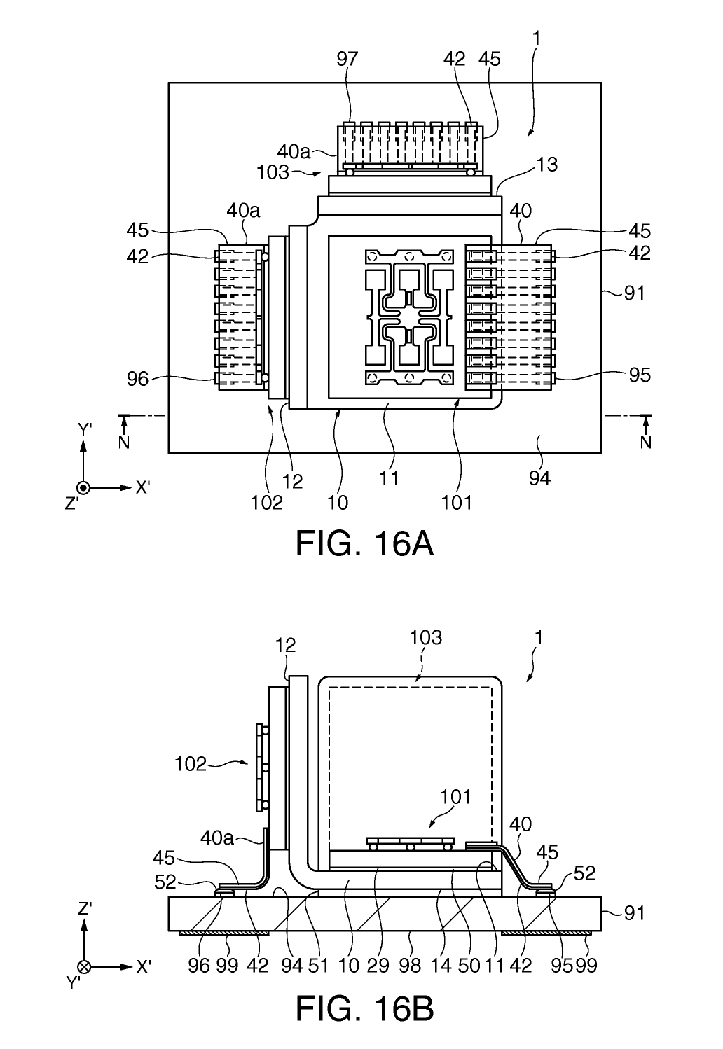

Then, as shown in FIGS. 16A and 16B, the sensor unit 101 is attached to the support face 11 lying along the top face 94 of the package base 91.

Specifically, the side of the IC chip 20 of the sensor unit 101 where the passive face 29 is located is attached to the support face 11 of the supporting member 10 by using the insulating adhesive 50 in a state in which the side is insulated from the supporting member 10.

Then, the wiring pattern layers 42 at the other ends 45 in the flexible wiring substrates 40 and 40a of the sensor units 101, 102, and 103 are attached to the internal terminals 95, 96, and 97 on the top face 94 of the package base 91 by the joining member 52.

As a result, the sensor module 1 is formed and the sensor module 1 is disposed in the package 90.

Lid Joining Process S12

Then, back in FIGS. 9A and 9B, the lid 93 is attached to the package base 91 by the joining member 53 under vacuum (in a state with a high degree of vacuum), and the package 90 is hermetically sealed. As a result, the inside of the package 90 is maintained under vacuum. Moreover, by doing so, the sensor module 1 is housed in the package 90.

Incidentally, the inside of the package 90 may be maintained under vacuum (in a state with a high degree of vacuum) by attaching the lid 93 to the package base 91 in the air, then reducing the pressure inside the package 90 via a through-hole provided in the package base 91 or the lid 93, and sealing the through-hole.

Through the processes etc. described above, the gyro sensor 2 shown in FIGS. 9A and 9B is obtained.

Incidentally, the order of the processes described above may be appropriately interchanged as necessary. For example, the supporting member preparing process S1 may be performed immediately before the sensor unit first joining process S9, the package preparing process S5 may be performed immediately before the supporting member joining process S10, and the flexible wiring substrate joining process S6 and the vibrating gyro element joining process S7 maybe interchanged.

In addition, in the sensor unit first joining process S9, the flexible wiring substrates 40a of the sensor unit 102 and 103 may be attached to the internal terminals 96 and 97.

As described above, since the sensor module 1 of the first embodiment is housed in the package 90, the gyro sensor 2 of the second embodiment can obtain the same effects as those of the first embodiment.

The main effects are as follows. Since the sensor module 1 that responds to three axes: the X′-axis, the Y′-axis, and the Z′-axis is housed in one package 90, the gyro sensor 2 can provide a gyro sensor that responds to three axes.

Therefore, since the gyro sensor 2 can considerably reduce the mounting space as compared to an existing configuration in which three gyro sensors, each responding to one axis, are used, it is possible to achieve further miniaturization of a target apparatus (an apparatus into which the gyro sensor is incorporated).

Moreover, since the gyro sensor 2 can provide a gyro sensor that responds to three axes with one package 90, it is possible to reduce the cost related to the package as compared to an existing configuration in which three gyro sensors, each responding to one axis, are used.

Moreover, in the gyro sensor 2, the IC chips 20 are attached to the three support faces 11, 12, and 13 of the supporting member 10 of the sensor module 1, the three support faces 11, 12, and 13 which are orthogonal to one another, and the one principal surfaces 30a (the other principal surfaces 30b) of the vibrating gyro elements 30 are attached to the sides of the IC chips 20 where the active faces 21 are located in such a way that the one principal surfaces 30a (the other principal surfaces 30b) lie along the support faces 11, 12, and 13.

As a result, since the orthogonality of the sensing axes (the X′-axis, the Y′-axis, and the Z′-axis) is determined by the processing accuracy of the supporting member 10, the gyro sensor 2 can eliminate dependence of the orthogonality of the sensing axes on the accuracy of installation of each gyro sensor (the accuracy of the mounting angle) in the target apparatus as in the existing configuration.

Furthermore, in the gyro sensor 2, the flexible wiring substrate 40 is attached to the external connection terminals 23 of the IC chip 20 of the sensor unit 101, and, on a face of the flexible wiring substrate 40, the face located on the side opposite to the side where the active face 21 of the IC chip 20 is located, the reinforcing layer 43 that improves stiffness is provided at least from an area in which the flexible wiring substrate 40 is attached to the external connection terminals 23 of the IC chip 20 to an area over the end 20a of the IC chip 20.

As a result, in the gyro sensor 2, the stiffness of the flexible wiring substrate 40 is improved at least from an area in which the flexible wiring substrate 40 is attached to the external connection terminals 23 of the IC chip 20 to an area over the end 20a of the IC chip 20.

Therefore, in the gyro sensor 2, when the sensor module 1 is attached to the package base 91, the flexible wiring substrate 40 seldom makes contact with the end 20a of the IC chip 20 as a result of the flexible wiring substrate 40 easily bending as described earlier.

As a result, the gyro sensor 2 can prevent a short circuit between the wiring pattern layer 42 of the flexible wiring substrate 40 and the IC chip 20 due to contact between the flexible wiring substrate 40 and the IC chip 20 and a short circuit between the wiring patterns of the wiring pattern layer 42 via the IC chip 20 when, for example, the active face 21 is exposed at the end 20a of the IC chip 20.

Incidentally, the gyro sensor 2 can provide a gyro sensor that responds to two axes by removing any one of the sensor units 101, 102, and 103 of the sensor module 1.

Moreover, by leaving any one of the sensor units 101, 102, and 103 of the sensor module 1 (removing the remaining two), the gyro sensor 2 can provide a gyro sensor that responds to one axis and does not have to change a position in which the package 90 is attached irrespective of the directions of the detection axes (the X′ -axis, the Y′ -axis, and the Z′ -axis) .

Furthermore, with the method for producing the gyro sensor 2, it is possible to produce and provide a gyro sensor that can obtain the effects described above.

In addition, in the method for producing the gyro sensor 2, the sensor units 102 and 103 are joined to the support faces 12 and 13 of the support faces 11, 12, and 13 of the supporting member 10, the support faces 12 and 13 orthogonal to the top face 94 of the package base 91, before the support face 11.

Thus, with the method for producing the gyro sensor 2, it is possible to hold the supporting member 10 by sucking in the support face 11 to which the sensor unit 101 is not joined with a suction apparatus or the like, the support face 11 lying along the top face 94 of the package base 91 in the supporting member 10. This makes it easy to deal with (transport) the supporting member 10.

As a result, since the method for producing the gyro sensor 2 makes it easy to attach, to the package base 91, the supporting member 10 to which the sensor units 102 and 103 are attached, it is possible to improve productivity.

Incidentally, in the gyro sensor 2, the supporting member 10 may be inverted and disposed in the package 90 in such a way that the opposite face 14 faces a ceiling's side of the lid 93 (the bottom face of the hollow portion 92). At this time, in the gyro sensor 2, the sensor unit 101 may be directly attached to the top face 94 of the package base 91 located immediately below the support face 11 or maybe attached to the opposite face 14 of the supporting member 10.

In addition, at this time, the directions in which the sensor units 102 and 103 are attached are also changed so that the flexible wiring substrates 40a of the sensor units 102 and 103 are located on the side of the package base 91 where the top face 94 is located.

Incidentally, in the embodiments described above, the base material of the vibrating gyro element 30 is crystal. However, the base material of the vibrating gyro element 30 is not limited to crystal. For example, the base material of the vibrating gyro element 30 may be piezoelectric bodies such as lithium tantalate (LiTaO₃), lithium tetraborate (Li₂B₄O₇), lithium niobate (LiNbO₃), lead zirconate titanate (PZT), zinc oxide (ZnO), and aluminum nitride (AlN) or a semiconductor such as silicon (Si).

Moreover, as the vibrating gyro element 30, in addition to the double T-type vibrating gyro element 30, various types of gyro elements such as a bipod tuning fork-type gyro element, a tripod tuning fork-type gyro element, an H-shaped tuning fork-type gyro element, a comb-type gyro element, an orthogonal gyro element, and a prism-type gyro element can be used.

Furthermore, in addition to a vibration-type gyro element, any gyro element may be used.

In addition, the method for driving and detecting the vibration of the vibrating gyro element 30 may be, in addition to a piezoelectric method using the piezoelectric effect of a piezoelectric body, an electrostatic method using Coulomb force, and a Lorenz method using magnetic force.

Moreover, the detection axis (the sensing axis) of the sensor element may be, in addition to an axis orthogonal to the principal surface of the sensor element, an axis parallel to the principal surface of the sensor element.

Furthermore, in the embodiments described above, a vibrating gyro element has been taken as an example of the sensor element of the sensor module. However, the sensor element of the sensor module is not limited to a vibrating gyro element. For example, the sensor element of the sensor module may be an acceleration sensing element responding to an acceleration, a pressure sensing element responding to a pressure, a weight sensing element responding to a weight, and the like.

Moreover, in the second embodiment described above, a gyro sensor has been taken as an example of the sensor device. However, the sensor device is not limited to a gyro sensor. For example, the sensor device may be an acceleration sensor using a sensor module provided with the acceleration sensing element, a pressure sensor using a sensor module provided with the pressure sensing element, a weight sensor using a sensor module provided with the weight sensing element, and the like.

Electronic Apparatus

The above-described sensor devices such as the gyro sensor, the acceleration sensor, the pressure sensor, and the weight sensor can be suitably used, as a device having a sensing function, in electronic apparatuses such as a digital still camera, a video camera, a navigation device, a vehicle body position detecting device, a pointing device, a game controller, a mobile telephone, and a head-mounted display, and, in each case, can provide an electronic apparatus that can obtain the effects described in the embodiments described above.

The entire disclosure of Japanese Patent Application No. 2011-056253, filed Mar. 15, 2011 is expressly incorporated by reference herein.

What is claimed is:

1. A sensor module comprising:
a supporting member having a first support face parallel to a first reference plane and a second support face parallel to a second reference plane which is orthogonal to the first reference plane or inclined relative to the first reference plane;
an IC chip having connection terminals and external connection terminals on a side thereof where one face is located, the IC chip which is attached, on a side thereof where the other face along the one face is located, to at least one of the first support face and the second support face;
a flexible wiring substrate attached to at least one of the external connection terminals of the IC chip; and
a sensor element having connection electrodes, the connection electrodes being attached to the connection terminals of the IC chip, the sensor element being disposed on the side of the IC chip where the one face is located, the sensor element whose principal surface lies along a support face of the first support face and the second support face of the supporting member, the support face to which the IC chip is attached,
wherein
on a face of the flexible wiring substrate, the face located on a side opposite to a side where the IC chip is located, a reinforcing section that improves the stiffness of the flexible wiring substrate is provided from an area in which the flexible wiring substrate is attached to the external connection terminals to an area over an end of the IC chip in a plan view.

2. The sensor module according to claim 1, wherein
the supporting member has a third support face parallel to a third reference plane which is orthogonal to the first reference plane and the second reference plane or inclined relative to the first reference plane and the second reference plane,
the IC chip is attached to the third support face, and
the sensor element is disposed on the side of the IC chip where the one face is located and the connection electrodes are attached to the connection terminals of the IC chip in such a way that the principal surface lies along the third support face.

3. The sensor module according to claim 1, wherein
the reinforcing section of the flexible wiring substrate contains metal.

4. The sensor module according to claim 1, wherein
the connection terminals of the IC chip are protrusion electrodes protruding toward the one face.

5. The sensor module according to claim 1, wherein
the IC chip is attached to two support faces of the first and second support faces and a third support face of the supporting member, the two support faces which are next to each other, the two support faces which are sides from which straight lines orthogonal to the two support faces extend so as to move away from each other.

6. The sensor module according to claim 1, wherein
in at least one of the first and second support faces and a third support face, a hollow portion is provided.

7. A sensor device comprising:
the sensor module according to claim 1; and
a package that houses the sensor module,
wherein
the sensor module is housed in the package.

8. A sensor device comprising:
the sensor module according to claim 2; and
a package that houses the sensor module,
wherein
the sensor module is housed in the package.

9. A sensor device comprising:
the sensor module according to claim 3; and
a package that houses the sensor module,
wherein
the sensor module is housed in the package.

10. A sensor device comprising:
the sensor module according to claim 4; and
a package that houses the sensor module,
wherein
the sensor module is housed in the package.

11. A sensor device comprising:
the sensor module according to claim 5; and
a package that houses the sensor module,
wherein
the sensor module is housed in the package.

12. A sensor device comprising:
the sensor module according to claim 6; and
a package that houses the sensor module,
wherein
the sensor module is housed in the package.

13. An electronic apparatus comprising the sensor module according to claim 1.

14. An electronic apparatus comprising the sensor module according to claim 2.

15. An electronic apparatus comprising the sensor module according to claim 3.

16. An electronic apparatus comprising the sensor module according to claim 4.

17. An electronic apparatus comprising the sensor module according to claim 5.

18. An electronic apparatus comprising the sensor module according to claim 6.

19. A method for producing a sensor device, comprising:
preparing a supporting member having a first support face parallel to a first reference plane and a second support face parallel to a second reference plane which is orthogonal to the first reference plane or inclined relative to the first reference plane or a supporting member having a first support face parallel to a first reference plane, a second support face parallel to a second reference plane which is orthogonal to the first reference plane or inclined relative to the first reference plane, and a third support face parallel to a third reference plane which is orthogonal to the first reference plane and the second reference plane or inclined relative to the first reference plane and the second reference plane;
preparing an IC chip provided with one face and the other face lying along the one face, the IC chip having connection terminals and external connection terminals on a side thereof where the one face is located;
preparing a sensor element having connection electrodes;
preparing a plurality of flexible wiring substrates, at least one of which has, on a face thereof located on a side opposite to a side where the IC chip is located, a reinforcing section that improves stiffness, the reinforcing section being provided at least from an area in which the flexible wiring substrate is attached to the external connection terminals of the IC chip to an area over an end of the IC chip;
preparing a package that houses the component elements;
attaching the flexible wiring substrate to the external connection terminals of the IC chip;
disposing the sensor element on a side of the IC chip where the one face is located and attaching the connection electrodes of the sensor element to the connection terminals of the IC chip in such a way that a principal surface of the sensor element lies along the one face or the other face;
performing adjustment and characteristic inspection on the sensor element and the IC chip via the flexible wiring substrate;
attaching a side of a sensor unit provided with the IC chip to which the sensor element and the flexible wiring substrate are attached, the side where the other face of the IC chip is located, to at least one of support faces of the first to third support faces of the supporting member, the support faces which are orthogonal to a supporting member joint surface of the package or inclined relative to the supporting member joint surface of the package;
attaching the supporting member to which the sensor unit is attached to the supporting member joint surface of the package;
attaching a side of another sensor unit to which the flexible wiring substrate provided with the reinforcing section is attached, the side where the other face of the IC chip is located, to a support face of the first to the third support faces of the supporting member attached to the supporting member joint surface of the package, the support face lying along the supporting member joint surface of the package; and
attaching each flexible wiring substrate of each sensor unit to the supporting member joint surface of the package.
